(19) United States
(12) Patent Application Publication
(10) Pub. No.: US 2026/0076047 A1
(43) Pub. Date: Mar. 12, 2026

(54) DISPLAY APPARATUS

(71) Applicant: LG Display Co., Ltd., Seoul (KR)

(72) Inventor: Insik SHIN, Paju-si (KR)

(73) Assignee: LG Display Co., Ltd., Seoul (KR)

(21) Appl. No.: 19/286,046

(22) Filed: Jul. 30, 2025

(30) Foreign Application Priority Data
Sep. 6, 2024 (KR) 10-2024-0121536

(51) Int. Cl. H10K 59/131; H10K 59/95

(52) U.S. Cl. CPC H10K 59/131; H10K 59/95

(57) ABSTRACT

A display apparatus can include a display panel having a main region, a sub-region including a pad area located inwardly more than an end of a substrate, and a bending region between the main region and the sub-region, and a flexible film attached to the sub-region on the substrate of the display panel. The flexible film includes a first film portion overlapping an area between the pad area and the end of the substrate and having a first thickness, and a second film portion overlapping the pad area and having a second thickness smaller than the first thickness.

### CROSS-REFERENCE TO RELATED APPLICATION

The present application claims priority to Korean Patent Application No. 10-2024-0121536, filed in the Republic of Korea on Sep. 6, 2024, the entire contents of which is hereby expressly incorporated by reference into the present application.

### BACKGROUND

### Field

The present disclosure relates to a display apparatus.

### Discussion of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a high contrast ratio, and is lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost.

The OLED display apparatus can include a display panel and a flexible film attached to the display panel. For structural stability, the display panel and the flexible film need to be firmly fixed.

### SUMMARY OF THE DISCLOSURE

The present disclosure is directed to providing a display apparatus having improve structural stability.

The present disclosure is also directed to providing a display apparatus in which it is possible to suppress or prevent damage to a display panel.

The present disclosure is also directed to providing a display apparatus in which a flexible film and a display panel can be more efficiently and smoothly fixed.

The present disclosure is also directed to providing a display apparatus in which it is possible to improve structural stability of a flexible film and a display panel.

Objects of the present disclosure are not limited to the above-described objects, and other technical objects can be inferred from the following embodiments.

According to one embodiment of the present disclosure, there is provided a display apparatus including a display panel including a main region, sub-region including a pad area disposed inward more than an end of a substrate, and a bending region between the main region and the sub-region, and a flexible film attached to the sub-region on the substrate of the display panel, wherein the flexible film includes a first film portion overlapping an area between the pad area and the end of the substrate and having a first thickness, and a second film portion overlapping the pad area and having a second thickness smaller than the first thickness.

According to another embodiment of the present disclosure, there is provided a display apparatus including a display panel including a main region, sub-region including a pad area disposed inward more than an end of a substrate, and a bending region between the main region and the sub-region, and a flexible film attached to the sub-region on the substrate of the display panel and having different thicknesses for each region, wherein the display panel includes a substrate, a first transistor on the substrate, a second transistor on the first transistor, a first protective layer on the second transistor, a connection electrode connected to the second transistor on the first protective layer, a second protective layer on the connection electrode, a light-emitting part disposed on the second protective layer and connected to the connection electrode, an encapsulation layer on the light-emitting part, and a touch part disposed on the encapsulation layer, wherein the touch part includes a touch buffer layer, a touch conductive layer on the touch buffer layer, and a touch organic layer on the touch conductive layer.

Detailed matters of other embodiments of the present disclosure are included in the detailed description and accompanying drawings.

According to the embodiments of the present disclosure, it is possible to improve structural stability.

According to the embodiments of the present disclosure, it is possible to suppress or prevent damage to a display panel and a flexible film.

According to the embodiments of the present disclosure, a flexible film and a display panel can be more efficiently and smoothly fixed.

According to the embodiments of the present disclosure, it is possible to improve structural stability of a flexible film and a display panel.

According to the embodiments of the present disclosure, it is possible to suppress or prevent damage to a display panel and a flexible film, thereby increasing the life of a display apparatus and reducing power consumption.

However, effects obtainable from the present disclosure are not limited to the above-described effects, and other effects that are not mentioned will be able to be clearly understood by those skilled in the art to which the present disclosure pertains based on the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one embodiment of the present disclosure.

FIG. 2 is a cross-sectional view illustrating a bent state of a display panel according to FIG. 1.

FIG. 3 is an exploded perspective view of the display apparatus according to one embodiment of the present disclosure.

FIG. 4 is a plan view of a rear surface of the display apparatus with a bent display panel according to one embodiment of the present disclosure.

FIG. 5 is a cross-sectional view along line C-C′ in FIG. 4.

FIG. 6 is a cross-sectional view along line D-D′ in FIG. 4.

FIG. 7 is an enlarged view of a cross section around a flexible film according to one embodiment of the present disclosure.

FIG. 8 is a cross-sectional view along line A-A′ in FIG. 1.

FIG. 9 is a specific cross-sectional view of a light-emitting part of FIG. 8.

FIG. 10 is a specific cross-sectional view of a light-emitting part according to a modified example of the present disclosure.

FIG. 11 is a cross-sectional view along line B-B′ in FIG. 1.

FIG. 12 is a cross-sectional view of a display apparatus according to yet another embodiment of the present disclosure.

### DETAILED DESCRIPTION OF THE EMBODIMENTS

Hereinafter, embodiments of the present disclosure will be described with reference to the accompanying drawings. In the specification, when a first component (or an area, a layer, a portion, etc.) is described as “on,” “connected,” or “coupled to” a second component, it means that the first component can be directly connected/coupled to the second component or a third component can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments of the present disclosure. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

For example, as long as “immediately” or “directly” is not used, one or more other portions can be positioned between two portions. The spatially relative terms “below or beneath,” “lower,” “above,” “upper,” etc. can be used to easily describe the correlation with one element or components and another element or components as shown in the drawings.

The spatially relative terms should be understood as including different directions of elements in use or operation in addition to the directions shown in the drawings. For example, in case of turning the element illustrated in the drawing upside down, an element described as being disposed “below” or “beneath” another element can be disposed “above” another element. Accordingly, the example term “below” can include both downward and upward directions.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance. Further, the term “can” fully encompasses all the meanings and coverages of the term “may” and vice versa.

Features of various embodiments of the present disclosure can be coupled or combined partially or entirely, various technological interworking and driving are made possible, and the embodiments can be implemented independently of each other or implemented together in an associated relationship.

Hereinafter, a display apparatus of the present disclosure will be described with reference to the accompanying drawings and embodiments of the present disclosure as follows. All the components of each display apparatus according to all embodiments of the present disclosure are operatively coupled and configured.

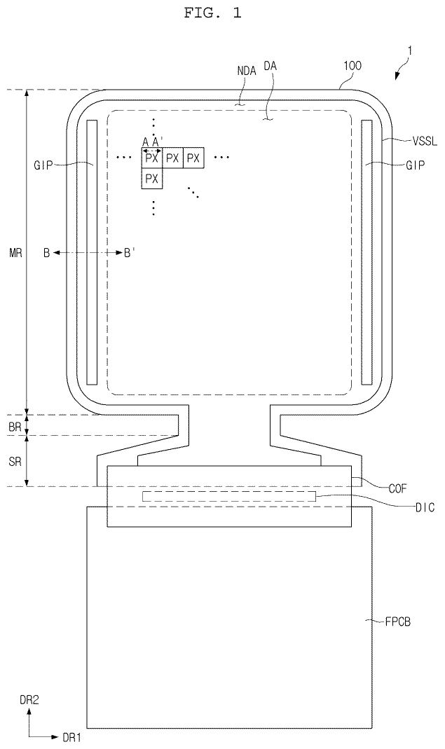

FIG. 1 is a plan view of a display apparatus according to one or more embodiments of the present disclosure.

Referring to FIG. 1, the display apparatus 1 according to one embodiment can include both a display function of displaying an image and a touch sensing function of sensing a user's touch, but is not limited thereto. For example, the display apparatus 1 can include only one of the display function of displaying an image and the touch sensing function of sensing a user's touch.

The display apparatus 1 can be an electroluminescent display apparatus or a micro light-emitting diode display apparatus that includes a touch sensor. The electroluminescent display apparatus including the touch sensor can be an organic light-emitting diode (OLED) display apparatus, a quantum-dot light-emitting diode display apparatus, or an inorganic light-emitting diode display apparatus.

The display apparatus 1 can include a display panel 100.

The display panel 100 can include a display area DA including a plurality of pixels PX and a non-display area NDA around the display area DA. The display panel 100 can further include a gate driving unit GIP and a low-potential voltage line VSSL that are disposed in the non-display area NDA.

The display area DA can be an area in which light is emitted to the outside to display a screen. The display area DA can further include a function of sensing a user's touch. In this case, the display area DA can correspond to a touch sensing area, but is not limited thereto.

The flat surface shape of the display area DA can have a rectangular shape. However, the embodiments of the present disclosure are not limited thereto, and the flat surface shape of the display area DA can be a square, circular, elliptical, or other polygonal shapes. For example, the display area DA can have a rectangular shape with rounded corners, but is not limited thereto and can also have a rectangular shape with angled corners.

In embodiments of the present disclosure, a first direction DR1 and a second direction DR2 are different directions and directions intersecting each other, for example, directions that intersect vertically in a plan view. In FIG. 1, the first direction DR1 can refer to a left-right direction in a plan view, and the second direction DR2 can refer to a vertical direction in a plan view. However, the directions described in the embodiments should be understood as indicating relative directions, and the embodiments are not limited to the described directions.

The display area DA can include edges extending in the first direction DR1 and edges extending in the second direction DR2. The non-display area NDA can surround the display area DA. The non-display area NDA can be disposed at one side and the other side of the display area DA in the first direction DR1 and one side and the other side of the display area DA in the second direction DR2.

The non-display area NDA can be an area in which light is not emitted to the outside so as not to display a screen. The non-display area NDA can be located around the display area DA. The non-display area NDA can surround the display area DA, but the embodiments of the present disclosure are not limited thereto. A bezel area of the display apparatus 1 can be defined by the non-display area NDA, but the embodiments of the present disclosure are not limited thereto.

The gate driving unit GIP can be disposed in the non-display area NDA located at one side and the other side of the display area DA in the first direction DR1.

The gate driving unit GIP can include a scan driver and an light-emitting signal driver. The scan driver can generate a scan signal in a row-sequential manner and supply the scan signal to the scan lines in order to drive one or more scan lines connected to each pixel PX row. The light-emitting signal driver can generate an light-emitting signal in a row-sequential manner and supply the light-emitting signal to light-emitting signal lines in order to drive one or more light-emitting signal lines connected to each pixel PX row.

The low-potential voltage line VSSL can be disposed outside the gate driving unit GIP on the non-display area NDA. For example, as illustrated in FIG. 1, the low-potential voltage line VSSL can extend from a flexible film COF, pass a sub-region SR and a bending region BR, can be located outside the gate driving unit GIP on the non-display area NDA, and disposed to surround the display area DA.

The low-potential voltage line VSSL can be disposed in the non-display area NDA to surround the display area DA. The low-potential voltage line VSSL can be disposed in the non-display area NDA with the display area DA and the gate driving unit GIP interposed therebetween. For example, the gate driving unit GIP can be disposed between the display area DA and the low-potential voltage line VSSL.

The low-potential voltage line VSSL can apply a low-potential voltage to the pixel PX. The low-potential voltage line VSSL can be electrically connected to the cathode electrode of the pixel PX to apply a low-potential voltage.

The non-display area NDA located at the other side of the display area DA in the second direction DR2 can extend further from a central portion of the other side toward the other side of the display area DA in the second direction DR2. A width of the non-display area NDA in the first direction DR1 further extending from the central portion of the other side toward the other side of the display area DA in the second direction DR2 can be smaller than a width of the non-display area NDA in the first direction DR1 adjacent to the other side of the display area DA in the second direction DR2.

The display apparatus 1 can include a main region MR, the sub-region SR, and the bending region BR between the main region MR and the sub-region SR.

The main region MR can be composed of the display area DA and the non-display area NDA surrounding four surfaces of the display area DA.

The bending region BR and the sub-region SR can be formed of portions extending further from the central portion of the other side of the display area DA in the second direction DR2 in the other side in the second direction DR2.

The bending region BR can be disposed between the sub-region SR and the main region MR.

The display apparatus 1 can include a printed circuit board FPCB, the flexible film COF, and a drive IC DIC.

The printed circuit board FPCB can be connected to the display panel 100 through the flexible film COF. The printed circuit board FPCB can be electrically connected to the pixel PX of the display area DA through the flexible film COF. The printed circuit board FPCB can be electrically connected to the flexible film COF. The printed circuit board FPCB and the flexible film COF can be electrically connected through a plurality of pads, leads, etc.

The printed circuit board FPCB can have various types of components disposed to supply the drive IC DIC with various signals, such as a gate control signal, a driving signal, a data signal, etc. The printed circuit board FPCB can be a PCB, but is not limited thereto.

The printed circuit board FPCB can be connected to the display panel 100 through the flexible film COF in the non-display area NDA. The printed circuit board FPCB can be provided as a single component, but is not limited thereto. The number of printed circuit boards FPCB can vary according to a design.

The flexible film COF can be attached to the sub-region SR of the display panel 100. The flexible film COF can be connected to the display panel 100 and the printed circuit board FPCB. The flexible film COF can be attached to each of the display panel 100 and the printed circuit board FPCB and electrically connected to each of the display panel 100 and the printed circuit board FPCB. For example, the display panel 100 and the printed circuit board FPCB can be electrically connected through the flexible film COF. The flexible film COF can be provided as a plurality of flexible films, but is not limited thereto.

The flexible film COF can be electrically connected to a pad part of the display panel 100. Accordingly, the flexible film COF can supply gate control signals, driving signals, power voltages, data voltages, etc. to the plurality of pixels PX and the gate driving unit GIP that are disposed in the display area DA.

The flexible film COF can be a flexible insulating film. The flexible film COF can include, for example, polycarbonate, polyethylene terephthalate, polyimide, polyamide, polyester, polyacrylate, polymethyl methacrylate, etc., but is not limited thereto.

The drive IC DIC can be mounted on the flexible film COF. The drive IC DIC can be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC can drive the display apparatus 1. The drive IC DIC can process data signals for displaying an image, various driving signals for processing the data signals, etc. The drive IC DIC can include a gate driver IC, a data driver IC, etc.

The display panel 100 according to one embodiment can further include a crack sensing pattern surrounding the low-potential voltage line VSSL, but the embodiments of the present disclosure are not limited thereto. The crack sensing pattern can be disposed to completely surround the display area DA. For example, the crack sensing pattern can be disposed outside the low-potential voltage line VSSL. However, the embodiments of the present disclosure are not limited thereto, and a part of the crack sensing pattern may not be disposed in the non-display area NDA of the other side of the display area DA in the second direction DR2.

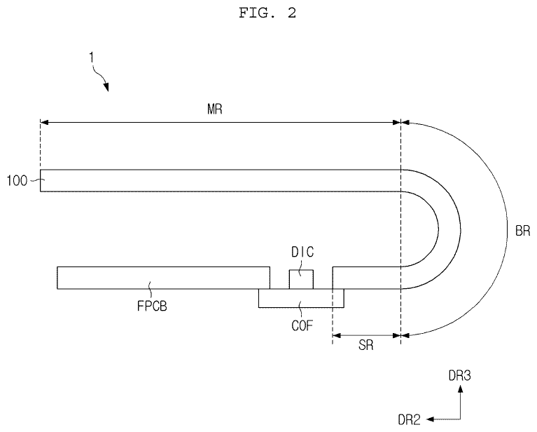

FIG. 2 is a cross-sectional view illustrating a bent state of the display panel according to FIG. 1.

Referring to FIG. 2, the bending region BR of the display panel 100 of the display apparatus 1 according to one embodiment can be bent in a thickness direction (or a third direction DR3). Accordingly, the main region MR and the sub-region SR can overlap each other in the thickness direction. The display panel 100 can be bent in such a manner that a lower surface of the main region MR faces a lower surface of the sub-region SR.

According to the bending of the display panel 100, the printed circuit board FPCB can be disposed under the display panel 100.

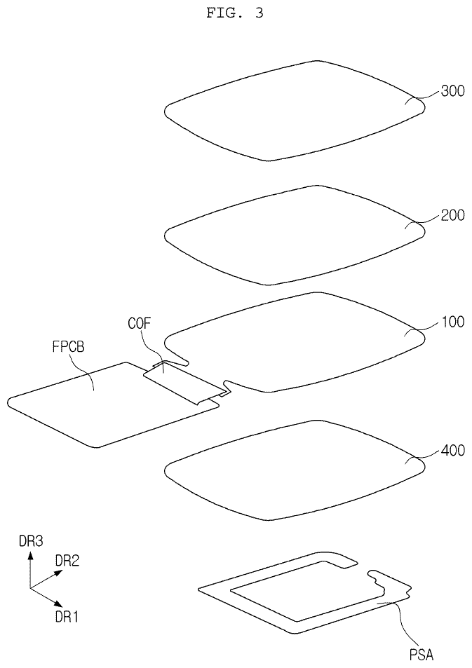

FIG. 3 is an exploded perspective view of the display apparatus according to one embodiment of the present disclosure.

Referring to FIG. 3, the display apparatus 1 can further include a polarizing layer 200 and a cover layer 300 that are disposed above the display panel 100, a back plate 400 disposed under the display panel 100, and a lower adhesive PSA disposed under the back plate 400.

The polarizing layer 200 can be disposed on the display panel 100. The polarizing layer 200 can be disposed above the display panel 100.

The polarizing layer 200 can polarize light emitted from the display panel 100 at a polarization angle. The polarizing layer 200 can emit light polarized at the polarization angle to the outside. The polarizing layer 200 can include a function of blocking reflection of light not including the light polarized at the polarization angle among external light.

The polarizing layer 200 can include a first phase retardation layer, a second phase retardation layer on the first phase retardation layer, and a polarizing layer on the second phase retardation layer, but the embodiments of the present disclosure are not limited thereto. FIG. 3 illustrates an example in which the polarizing layer 200 and the display panel 100 are separated, but the embodiments of the present disclosure are not limited thereto, and the polarizing layer 200 can be included in the display panel 100.

The cover layer 300 can be disposed on the polarizing layer 200. The cover layer 300 can be disposed above the polarizing layer 200.

The cover layer 300 can protect members (e.g., the display panel 100) disposed below the cover layer 300 from the outside.

The cover layer 300 can be formed of a glass material including glass or quartz, but the embodiments of the present disclosure are not limited thereto. The cover layer 300 can be a cover layer formed by chemical reinforcement, but the embodiments of the present disclosure are not limited thereto. The cover layer 300 can be a cover window, a window cover, or a cover member, but the embodiments of the present disclosure are not limited thereto.

The cover layer 300 can be formed of a glass material, and in this case, the cover layer 300 can be damaged by an external force, resulting in glass fragments. To prevent the shattering of the glass fragments due to the damage to the cover layer 300 or increase the durability of the cover layer 300, the display apparatus 1 can further include at least one additional layer on the cover layer 300.

The back plate 400 can be disposed on the display panel 100. The back plate 400 can be disposed under the display panel 100.

The back plate 400 can serve to support the display panel 100 and protect the display panel 100. The back plate 400 can be a rigid plate, but is not limited thereto.

The display apparatus 1 can further include an adhesive layer disposed between the display panel 100 and the polarizing layer 200, between the polarizing layer 200 and the cover layer 300, and between the display panel 100 and the back plate 400. The adhesive layer disposed between the layers can adhere the components disposed above and under the respective layers.

The adhesive layer disposed between the display panel 100 and the polarizing layer 200, between the polarizing layer 200 and the cover layer 300, and between the display panel 100 and the back plate 400 can include a transparent adhesive member. The transparent adhesive member can be formed of, for example, an optical clear adhesive, an optically cleared resin, or a transparent pressure sensitive adhesive (PSA), but is not limited thereto.

However, the embodiments of the present disclosure are not limited thereto, and the adhesive layer disposed between the display panel 100 and the back plate 400 can be formed of a non-transparent adhesive. For example, the adhesive can be formed of a PSA, but is not limited thereto.

The lower adhesive PSA can be disposed under the back plate 400. The lower adhesive PSA can be bent to fixedly attach the printed circuit board FPCB and the back plate 400 that are disposed under the display panel 100.

The lower adhesive PSA can be formed of a PSA. When the lower adhesive PSA includes a PSA, the lower adhesive PSA can be a double-sided adhesive.

The display apparatus 1 can further include a light-blocking film. The light-blocking film can be disposed under the back plate 400 and disposed outside the lower adhesive PSA. The light-blocking film can block or absorb external light traveling toward the display panel 100 and absorb an external impact to protect the display panel 100.

The display apparatus 1 can further include a cover protective layer disposed above the cover layer 300. The cover protective layer can be disposed on the cover layer 300 to protect the cover layer 300. The cover protective layer can mitigate an impact applied to the cover layer 300 and suppress or prevent damage, such as scratches, which can be applied to the cover layer 300.

The display apparatus 1 can further include a hot bar flex connected to the printed circuit board FPCB. The hot bar flex can be connected to the printed circuit board FPCB through a connector and used to test the display panel 100. In addition, the display apparatus 1 can further include a flex fixing tape for attaching the hot bar flex to the printed circuit board FPCB.

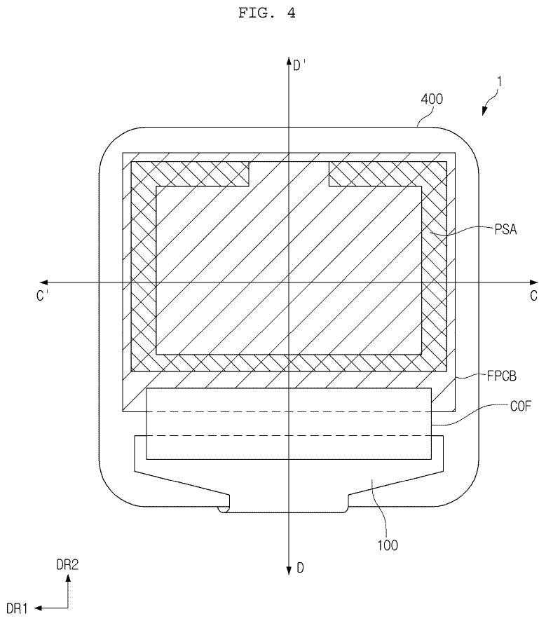

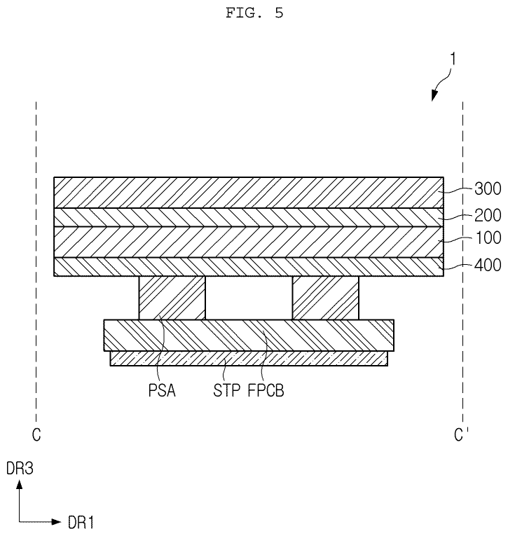

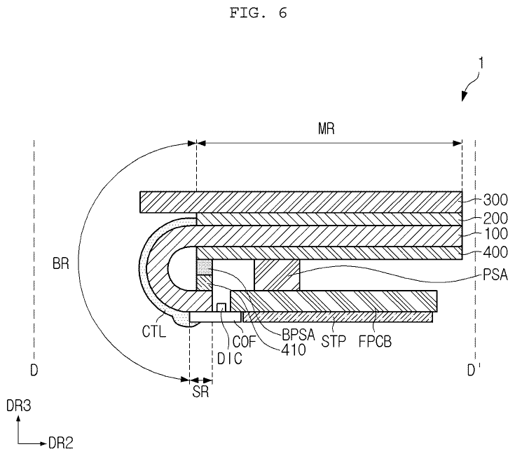

FIG. 4 is a plan view of a rear surface of the display apparatus with a bent display panel according to an embodiment of the present disclosure. FIG. 5 is a cross-sectional view along line C-C′ in FIG. 4. FIG. 6 is a cross-sectional view along line D-D′ in FIG. 4.

For convenience of description, the cross-sectional views of FIGS. 5 and 6 are illustrated according to the stacking order of FIG. 3.

Referring to FIGS. 4 to 6, the lower adhesive PSA can be disposed between the display panel 100 and the printed circuit board FPCB.

The lower adhesive PSA can overlap the display panel 100 in the thickness direction (the third direction DR3) and overlap the printed circuit board FPCB in the thickness direction (the third direction DR3).

The entire area of the lower adhesive PSA can overlap the display panel 100 in the thickness direction (the third direction DR3) and overlap the printed circuit board FPCB in the thickness direction (the third direction DR3).

When the back plate 400 is disposed under the display panel 100, the lower adhesive PSA can be disposed between the back plate 400 and the printed circuit board FPCB. In this case, the lower adhesive PSA can be in direct contact with the printed circuit board FPCB and the back plate 400. The entire area of the lower adhesive PSA can overlap the back plate 400 in the thickness direction (the third direction DR3).

The lower adhesive PSA can be disposed along an edge of the printed circuit board FPCB. However, the lower adhesive PSA may not be disposed in a part of one side in the second direction DR2, but is not limited thereto.

The lower adhesive PSA can be disposed inward by a predetermined distance from side surfaces of the printed circuit board FPCB. For example, side surfaces of the lower adhesive PSA can be disposed inward from the side surfaces of the printed circuit board FPCB.

The display apparatus 1 can further include a bending plate 410, a bending adhesive BPSA, a protective coating layer CTL, and a protective tape STP.

The bending plate 410 can be formed of the same material as the back plate 400, but is not limited thereto.

The bending plate 410 can be disposed on the sub-region SR under the display panel 100. The bending plate 410 can protect the sub-region SR of the display panel 100.

Due to the bending of the display panel 100, the bending plate 410 can be disposed under the back plate 400 to face the back plate 400.

Due to the bending of the display panel 100, the bending adhesive BPSA can be disposed between the back plate 400 and the bending plate 410 that face each other.

The bending adhesive BPSA can mutually adhere the back plate 400 and the bending plate 410. The bending adhesive BPSA can include a PSA. When the bending adhesive BPSA includes a PSA, the bending adhesive BPSA can be a double-sided adhesive.

The protective coating layer CTL can be disposed on the display panel 100. The protective coating layer CTL can be disposed in the bending region BR. The protective coating layer CTL can extend to the sub region SR to cover a part of the flexible film COF, but is not limited thereto.

The protective coating layer CTL can extend to a side surface of the polarizing layer 200 and can be in direct contact with the side surface of the polarizing layer 200, but is not limited thereto.

The protective coating layer CTL can be bent together as the bending region BR of the display panel 100 is bent. The protective coating layer CTL can be flexible.

The protective coating layer CTL can be formed of a light (e.g., UV light, visible light, etc.) curable acrylic resin. To prevent penetration of moisture through the protective coating layer CTL, one or more hygroscopic materials (getters) can be mixed into the protective coating layer CTL.

Various resin application methods, such as slit coating, jetting, etc., can be used to coat a predetermined surface with the protective coating layer CTL.

The protective coating layer CTL can protect components thereunder from damage during a curing process. The protective coating layer CTL can protect the components above the display panel 100 from an external impact and suppress or prevent penetration of external air and moisture.

The protective tape STP can be disposed on the printed circuit board FPCB. The printed circuit board FPCB can be disposed between the lower adhesive PSA and the protective tape STP. The protective tape STP can be disposed on a different surface from the lower adhesive PSA. For example, when the display panel 100 is bent, the lower adhesive PSA can be disposed on an upper surface of the printed circuit board FPCB, and the protective tape STP can be disposed on a lower surface of the printed circuit board FPCB.

The protective tape STP can protect lines and components disposed on the printed circuit board FPCB from damage.

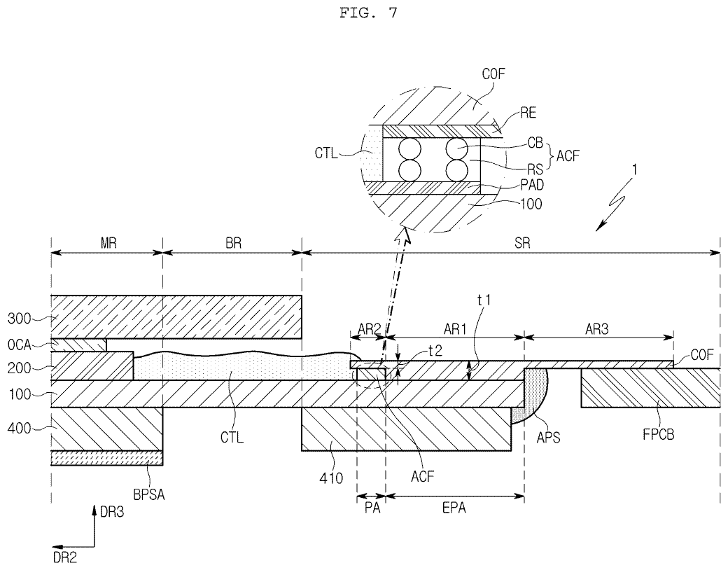

FIG. 7 is an enlarged view of a cross section around a flexible film according to an embodiment of the present disclosure.

For convenience of description, FIG. 7 illustrates a cross section of the display panel 100 that is not bent.

Referring to FIG. 7, the display apparatus 1 can further include a conductive adhesive ACF and an encapsulation member APS.

The display apparatus 1 can further include a bonding member OCA disposed between the polarizing layer 200 and the cover layer 300, a lead electrode RE disposed on the flexible film COF, and a pad electrode PAD disposed on the display panel 100.

The bonding member OCA can adhere the polarizing layer 200 to the cover layer 300. The bonding member OCA can be transparent. The bonding member OCA can include a transparent adhesive member. The transparent adhesive member can be formed of, for example, an optical clear adhesive, an optically cleared resin, or a transparent PSA, but is not limited thereto.

A side surface of the bonding member OCA can be disposed inward more than the side surface of the polarizing layer 200. An end of the bonding member OCA can be disposed inward more than an end of the polarizing layer 200.

For example, the side surface of the polarizing layer 200 can be disposed to protrude outward more than the side surface of the bonding member OCA. The end of the polarizing layer 200 can be disposed to protrude outward more than the end of the bonding member OCA.

The lead electrode RE can be disposed to face the display panel 100. The lead electrode RE can be disposed to face the pad electrode PAD of the display panel 100. The lead electrode RE can be provided as a plurality of lead electrodes.

The pad electrode PAD can be disposed to face the flexible film COF. The pad electrode PAD can be disposed to face the lead electrode RE disposed on the flexible film COF. The pad electrode PAD can be provided as a plurality of pad electrodes.

The lead electrode RE and the pad electrode PAD can be disposed to overlap each other in the thickness direction (the third direction DR3). The lead electrode RE and the pad electrode PAD can be electrically connected by the conductive adhesive ACF.

The display panel 100 can further include a pad area PA and a dummy area EPA. The pad area PA and the dummy area EPA can be disposed in the sub-region SR of the display panel 100.

A plurality of pad electrodes PAD can be disposed in the pad area PA. The pad area PA can overlap the flexible film COF in the thickness direction (the third direction DR3) and can be adhered to the flexible film COF in the overlapping area.

The dummy area EPA can be disposed outside the pad area PA. The dummy area EPA can be disposed at the other side of the pad area PA in the second direction DR2. The dummy area EPA can be disposed between the pad area PA and an end of the display panel. Dummy lines and/or dummy electrodes can be disposed in the dummy area EPA.

One ends of the dummy lines and/or the dummy electrodes can be connected to the pad area PA, but the other ends can be exposed to the side surface (or the end) of the display panel 100. The other ends of the dummy lines and/or the dummy electrodes can be covered by the encapsulation member APS.

The dummy lines and/or the dummy electrodes are connected to test pads disposed on the dummy area in which the other ends extend outward from the sub-region SR of the display panel 100, but, since the dummy area in which the test pads are disposed is cut out by trimming, the other ends can be exposed to the side surface (or the end) of the display panel 100.

The conductive adhesive ACF can be formed of an anisotropic conductive film, but is not limited thereto. The conductive adhesive ACF can be disposed in an area in which the display panel 100 and the flexible film COF overlap each other in the thickness direction (the third direction DR3).

The conductive adhesive ACF can adhere the display panel 100 to the flexible film COF and electrically connect the display panel 100 to the flexible film COF. Specifically, the conductive adhesive ACF can electrically connect the pad part PA (or the pad electrode PAD) of the display panel 100 to a lead part (or the lead electrode RE) of the flexible film COF.

The conductive adhesive ACF can include an adhesive member RS and a conductive ball CB. The adhesive member RS can be disposed between the flexible film COF and the display panel 100 so that the flexible film COF and the display panel 100 can be adhered by the adhesive member RS.

The adhesive member RS can be a curable organic polymer that has adhesive properties and is cured by heat or light. Specifically, the resin layer can be formed of a thermosetting resin and can include an epoxy resin, a phenol resin, a urea resin, a melamine resin, an unsaturated polyester resin, a resorcinol resin, etc., but is not limited thereto.

The conductive ball CB can be disposed in the adhesive member RS. The conductive ball CB can be provided as a plurality of conductive balls. The plurality of conductive balls CB can be disposed in a dispersed manner in the adhesive member RS.

The conductive ball CB can include conductivity. The conductive ball CB can be formed of a metal, such as gold (Au), silver (Ag), tin (Tin), nickel (Ni), chromium (Cr), iron (Fc), cobalt (Co), platinum (Pt), copper (Cu), etc., and an alloy thereof. Alternatively, the conductive ball CB can be formed of a core including glass, ceramic, or a polymer resin, and a metal formed on a surface of the core, and an alloy thereof, but is not limited thereto.

The conductive ball CB can be disposed between the pad electrode PAD and the lead electrode RE that overlap each other. The conductive ball CB can be in direct contact with the pad electrode PAD and the lead electrode RE that overlap each other. The conductive ball CB can electrically connect the pad electrode PAD to the lead electrode RE.

The encapsulation member APS can be disposed on a side surface of the display panel 100. The encapsulation member APS can be disposed on a side surface of the sub-region SR of the display panel 100.

The encapsulation member APS disposed on the side surface of the display panel 100 can be disposed to extend to a lower surface of the display panel 100. The encapsulation member APS can be formed of a resin, but is not limited thereto.

Here, the side surface of the display panel 100 can refer to a surface facing the side surface of the printed circuit board FPCB in the cross-sectional view of FIG. 7.

The encapsulation member APS can encapsulate the side surface of the display panel 100. For example, the encapsulation member APS can be disposed on the display panel 100 to cover and encapsulate electrodes and lines exposed to the side surface of the display panel 100. The encapsulation member APS can encapsulate the side surface of the display panel 100, thereby suppressing or preventing the penetration of external air and moisture, etc. and suppressing or preventing damage to the display panel 100.

The flexible film COF can include a first film portion AR1, a second film portion AR2, and a third film portion AR3 that have different thicknesses. The first film portion AR1 can have a first thickness t1, and the second film portion AR2 and the third film portion AR3 can have a second thickness t2. The first thickness t1 can be greater than the second thickness t2.

The second film portion AR2 and the third film portion AR3 can have the same thickness, but are not limited thereto.

The first film portion AR1 can be disposed between the second film portion AR2 and the third film portion AR3. The first film portion AR1 can overlap the dummy area EPA of the display panel 100. The first film portion AR1 can be in direct contact with the display panel 100, but is not limited thereto. The first film portion AR1 can be in direct contact with the encapsulation member APS, but is not limited thereto.

The second film portion AR2 can extend from the first film portion AR1 to one side in the second direction DR2. The second film portion AR2 can overlap the pad area PA of the display panel 100. The lead electrode RE can be disposed on the second film portion AR2. The second film portion AR2 may not be in direct contact with the encapsulation member APS.

The third film portion AR3 can extend from the first film portion AR1 to the other side in the second direction DR2. The third film portion AR3 can extend further outward from the end of the display panel 100. In the cross-sectional view of FIG. 7 in which the bending region BR of the display panel 100 is not bent, the third film portion AR3 may not overlap the display panel 100. The third film portion AR3 can be in direct contact with the encapsulation member APS, but is not limited thereto.

Since the first film portion AR1 has a relatively great thickness, a part of the first film portion AR1 can be disposed on a side surface of the conductive adhesive ACF. The first film portion AR1 can fill an upper area of the display panel 100 outside the conductive adhesive ACF.

In the flexible film COF, the first film portion AR1 can protrude toward the display panel 100. Accordingly, the first film portion AR1 can fill the upper area of the display panel 100. Specifically, when the first film portion AR1 does not protrude toward the display panel 100, the flexible film COF and the dummy area EPA of the display panel 100 can be spaced apart from each other, but, since the first film portion AR1 protrudes from one surface of the flexible film COF toward the display panel 100, the first film portion AR1 can fill a spacing space between the flexible film COF and the dummy area EPA of the display panel 100.

Since dummy circuits and/or dummy electrodes are disposed in the dummy area EPA of the display panel 100, when the dummy area EPA has a length greater than a predetermined length in the second direction DR2, it can be difficult to sufficiently fill the spacing space between the flexible film COF and the dummy area EPA using a material, such as a resin.

However, when the first film portion AR1 has a relatively great thickness and protrudes toward the dummy area EPA of the display panel 100, even when the dummy area EPA is disposed outside (at the other side in the second direction DR2) of the pad area PA and includes dummy circuits and/or dummy electrodes, the first film portion AR1 can smoothly fill the spacing space between the flexible film COF and the dummy area EPA without being affected by a length of the dummy area EPA in the second direction DR2.

Since the flexible film COF has a relatively great thickness in the area in which it overlaps the dummy area EPA, the flexible film COF and the display panel 100 can be fixed more efficiently and smoothly, thereby improving the structural stability of the display apparatus 1. Furthermore, it is possible to suppress or prevent damage to the flexible film COF and the display panel 100 due to a collision between the flexible film COF and the display panel 100, increase the life of the display apparatus, and reduce power consumption.

Hereinafter, the display panel 100 according to examples of the present disclosure will be described in detail.

First, the display area DA of the display panel 100 will be described.

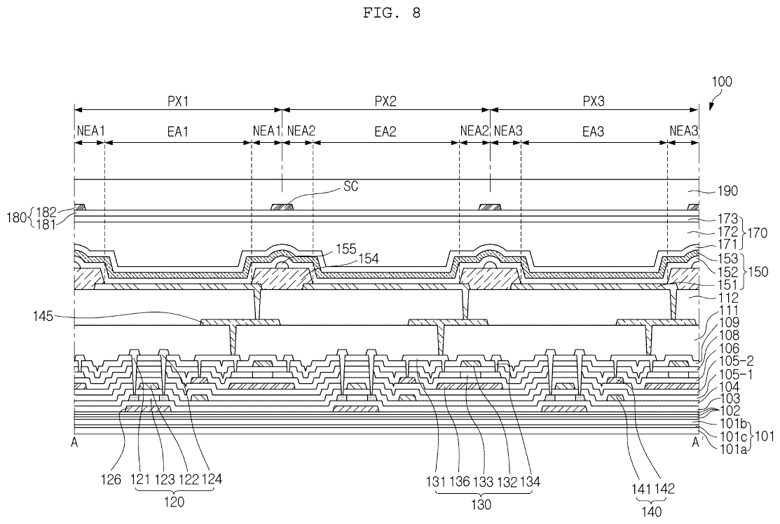

FIG. 8 is a cross-sectional view along line A-A′ in FIG. 1.

Referring to FIG. 8, the pixel PX (see FIG. 1) of the display panel 100 can include a plurality of sub-pixels PX1, PX2, and PX3. A first sub-pixel PX1 can be a red sub-pixel, a second sub-pixel PX2 can be a green sub-pixel, and a third sub pixel PX3 can be a blue sub-pixel, but the embodiments of the present disclosure are not limited thereto. In some embodiments of the present disclosure, the pixel PX can further include a fourth sub-pixel, and the fourth sub-pixel can be a white sub-pixel, but the embodiments of the present disclosure are not limited thereto.

The display panel 100 can include a substrate 101, a first thin film transistor 120, a second thin film transistor 130, a light-emitting part 150, an encapsulation part 170, and a touch part 180. The display panel 100 can include at least one panel insulating layer and at least one touch insulating layer between the substrate 101 and the light-emitting part 150. The at least one panel insulating layer can include at least one of the buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and at least one touch insulating layer can include a touch buffer layer 181. The 3-1 insulating layer 105-1 and the 3-2 insulating layer 105-2 are also referred to as the third insulating layers 105-1 and 105-2 hereinafter.

The substrate 101 can include one or more plastic materials. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The buffer layer 102 can be disposed on the substrate 101. The buffer layer 102 can minimize or delay the diffusion of moisture or oxygen penetrating the substrate 101. The buffer layer 102 can be formed by alternately stacking silicon nitride (SiNₓ) and silicon oxide (SiOₓ) at least once, but the embodiments of the present disclosure are not limited thereto.

A first light-blocking layer 126 can be disposed on the buffer layer 102. The first light-blocking layer 126 can prevent light from transmitting a first semiconductor layer 123 of the first thin film transistor 120. For example, the first semiconductor layer 123 can be disposed to overlap the first light-blocking layer 126. The first light-blocking layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 can be disposed on the buffer layer 102 and the first light-blocking layer 126. The first insulating layer 103 can prevent a short circuit between a component of the first thin film transistor 120 and the first light-blocking layer 126. The first insulating layer 103 can be formed of the same material as the buffer layer 102, but the embodiments of the present disclosure are not limited thereto. For example, the first insulating layer 103 can be formed of an inorganic insulation material, such as silicon nitride (SiNₓ) or silicon oxide (SiOₓ), but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor can be formed of the polycrystalline semiconductor layer.

The second insulating layer 104 can be disposed on the first semiconductor layer 123. The second insulating layer 104 can be formed of the same material as the first insulating layer 103 and can prevent a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 can be disposed along with a gate line.

The third insulating layers 105-1 and 105-2 can be disposed on the first gate electrode 122. The third insulating layers 105-1 and 105-2 can be formed by alternately stacking silicon nitride (SiNₓ) and silicon oxide (SiOₓ) at least once, but the embodiments of the present disclosure are not limited thereto. For example, the 3-1 insulating layer 105-1 can include silicon oxide (SiOₓ), and the 3-2 insulating layer 105-2 can include silicon nitride (SiNₓ), but the embodiments of the present disclosure are not limited thereto.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can be formed of a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 can be disposed along with a data line. For example, the data line can be formed of the same material as the first source electrode 121 and the first drain electrode 124 and formed on the same layer as the first source electrode 121 and the first drain electrode 124, but the embodiments of the present disclosure are not limited thereto.

A storage electrode 140 can be disposed to be spaced apart from the first thin film transistor 120. The storage electrode 140 can include a first storage electrode 141 and a second storage electrode 142.

The first storage electrode 141 can be formed of the same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-blocking layer 136 can be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 can be disposed to overlap the second light-blocking layer 136.

The fourth insulating layer 106 can be disposed on the second light-blocking layer 136. The fourth insulating layer 106 can be formed of the same material as the first insulating layer 103, the second insulating layer 104, or the third insulating layers 105-1 and 105-2, but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108.

The second gate electrode 132 can be formed of the same material as the first gate electrode 122. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 can be disposed on the second gate electrode 132. The sixth insulating layer 109 can be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142.

The first thin film transistor 120 can be a driving transistor, and the second thin film transistor 130 can be a switching transistor, but the embodiments of the present disclosure are not limited thereto.

A first protective layer 111 can be disposed on the first source electrode 121 and the first drain electrode 124.

The first protective layer 111 can planarize an upper portion of the first thin film transistor 120 and protect the first thin film transistor 120. The first protective layer 111 can be formed of an organic material. For example, the first protective layer 111 can be formed of an organic material including an acrylic resin, an epoxy resin, a phenolic resin, a polyamide resin, or a polyimide resin, but the embodiments of the present disclosure are not limited thereto.

A second protective layer 112 can be disposed on the first protective layer 111. The second protective layer 112 can be formed of the same material as the first protective layer 111, but the embodiments of the present disclosure are not limited thereto.

In some embodiments of the present disclosure, a third protective layer can be further disposed on an upper surface of the second protective layer 112, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same material as the first source electrode 121 and the first drain electrode 124, but the embodiments of the present disclosure are not limited thereto.

The connection electrode 145 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include the anode electrode 151, an organic layer 152, and the cathode electrode 153.

The anode electrode 151 can be disposed on the second protective layer 112. The anode electrode 151 can be electrically connected to the first thin film transistor 120 through a contact hole formed in the second protective layer 112. The anode electrode 151 can be a reflective electrode that reflects light, but the embodiments of the present disclosure are not limited thereto. The anode electrode 151 can include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure are not limited thereto. For example, the organic layer 152 of the display panel 100 according to one embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto. Hereinafter, a specific structure of the organic layer 152 according to one embodiment will be described.

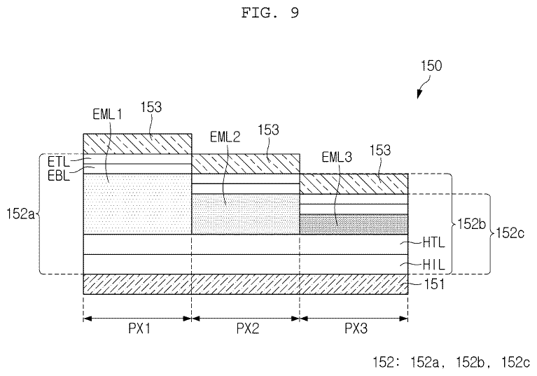

FIG. 9 is a specific cross-sectional view of a light-emitting part of FIG. 8.

Further referring to FIG. 9, the light-emitting part 150 can include the first sub-pixel PX1, the second sub-pixel PX2, and the third sub-pixel PX3.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

The hole injecting layer HIL can be disposed on the anode electrode 151. The hole injecting layer HIL can be located between the anode electrode 151 and the light-emitting layers EML1, EML2, and EML3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be formed integrally across the sub-pixels PX1, PX2, and PX3. The hole transporting layer HTL can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN,N′-diphenyl benzidine), s-TAD, and MTDATA (4,4′,4″-Tris(N-3-methylphenyl-N-phenyl-amino)-triphenylamine), but the embodiments of the present disclosure are not limited thereto.

The light-emitting layers EML1, EML2, and EML3 can be disposed on the hole transporting layer HTL. The first light-emitting layer EML1 can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different. For example, the first light-emitting layer EML1 can be formed in a thickness of 600 to 800 Å, the second light-emitting layer EML2 can be formed in a thickness of 300 to 500 Å, and the third light-emitting layer EML3 can be formed in a thickness of 100 to 300 Å, but the embodiments of the present disclosure are not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can also be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 can be disposed on the electron transporting layer ETL.

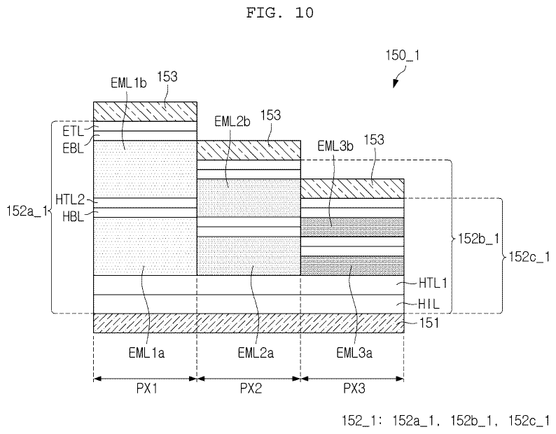

FIG. 10 is a specific cross-sectional view of a light-emitting part according to a modified example of the present disclosure.

Referring to FIGS. 8 and 10, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 can be physically separated, but the lower layers and upper layers of the light-emitting layers can be formed integrally across the sub-pixels PX1, PX2, and PX3. The thickness of each light-emitting layer can be different. For example, the thickness of the first light-emitting layer of the first sub-pixel can be the greatest, the thickness of the second light-emitting layer of the second sub-pixel can be the second greatest, and the thickness of the third light-emitting layer of the third sub-pixel can be the smallest, but the embodiments of the present disclosure are not limited thereto. In addition, the light-emitting layers of each organic layer 152a_1, 152b_1, or 152c_1 can be provided as two or more light-emitting layers.

The hole injecting layer HIL can be disposed on the anode electrode 151. The hole injecting layer HIL can be located between the anode electrode 151 and the light-emitting layers EML1a, EML2a, and EML3a. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 can be disposed on the hole injecting layer HIL. The first hole transporting layer HTL1 can be located between the hole injecting layer HIL and light-emitting layers EML1a, EML2a, and EML3a. The first hole transporting layer HTL1 can be formed integrally across the sub-pixels PX1, PX2, and PX3. The first hole transporting layer HTL1 can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN,N′-diphenyl benzidine), S-TAD, and MTDATA (4,4′,4″-Tris(N-3-methylphenyl-N-phenyl-amino)-triphenylamine), but the embodiments of the present disclosure are not limited thereto.

The light-emitting layers EML1a, EML2a, and EML3a can be disposed on the first hole transporting layer HTL1. A 1-1 light-emitting layer EML1a can be disposed in the first sub-pixel PX1, a 2-1 light-emitting layer EML2a can be disposed in the second sub-pixel PX2, and a 3-1 light-emitting layer EML3a can be disposed in the third sub-pixel PX3. Each of the light-emitting layers EML1a, EML2a, and EML3a can be the same as each of the light-emitting layers EML1, EML2, and EML3 of FIG. 4.

A thicknesses of each light-emitting layer EML1a, EML2a, or EML3a can be different. For example, the 1-1 light-emitting layer EML1a can be formed in a thickness of 600 to 800 Å, the 2-1 light-emitting layer EML2a can be formed in a thickness of 300 to 500 Å, and the 3-1 light-emitting layer EML3a can be formed in a thickness of 100 to 300 Å, but the embodiments of the present disclosure are not limited thereto.

A hole blocking layer HBL can be disposed on each light-emitting layer EML1a, EML2a, or EML3a. The hole blocking layer HBL can also be disposed integrally across the sub-pixels PX1, PX2, and PX3.

A second hole transporting layer HTL2 can be disposed on the hole blocking layer HBL. The second hole transporting layer HTL2 can be disposed between the hole blocking layer HBL and the light-emitting layers EML1b, EML2b, and EBL3b. The second hole transporting layer HTL2 can also be formed integrally across the sub-pixels PX1, PX2, and PX3. A material of the second hole transporting layer HTL2 can be the same as a material of the first hole transporting layer HTL1, but the embodiments of the present disclosure are not limited thereto.

The light-emitting layers EML1b, EML2b, and EML3b can be disposed on the second hole transporting layer HTL2. A 1-2 light-emitting layer EML1b can be disposed in the first sub-pixel PX1, a 2-2 light-emitting layer EML2b can be disposed in the second sub-pixel PX2, and a 3-2 light-emitting layer EML3b can be disposed in the third sub-pixel PX3. Each of the light-emitting layers EML1b, EML2b, and EML3b can be the same as each of the light-emitting layers EML1a, EML2a, and EML3a.

A thicknesses of each light-emitting layer EML1b, EML2b, or EML3b can be different. For example, the 1-2 light-emitting layer EML1b can be formed in a thickness of 600 to 800 Å, the 2-2 light-emitting layer EML2b can be formed in a thickness of 300 to 500 Å, and the 3-2 light-emitting layer EML3b can be formed in a thickness of 100 to 300 Å, but the embodiments of the present disclosure are not limited thereto.

An electron blocking layer EBL can be disposed on each light-emitting layer EML1b, EML2b, or EML3b. The electron blocking layer EBL can also be disposed integrally across the sub-pixels PX1, PX2, and PX3.

An electron transporting layer ETL can be disposed on the electron blocking layer EBL. The electron transporting layer ETL can also be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 can be disposed on the electron transporting layer ETL.

Referring back to FIG. 8, the cathode electrode 153 can be disposed on the organic layer 152. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

A bank 154 can be disposed to expose the anode electrode 151. The bank 154 can define openings (or the light-emitting areas EA1, EA2, and EA3) of the sub-pixels PX1, PX2, and PX3 and can be disposed to cover an edge portion (or a periphery) of the anode electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3.

The bank 154 can be formed of an organic insulation material, such as benzocyclobutene (BCB), polyimide, photo-acryl, etc.

However, the embodiments of the present disclosure are not limited thereto, and the bank 154 can include a black-based material. For example, the bank 154 can be formed of a material containing black pigment, or an organic material, such as a benzocyclobutene resin, a polyimide resin, an acrylic resin, a photosensitive polymer, etc. In this case, when the bank 154 is formed of a material containing black pigment or black dye, the bank 154 can be an opaque bank. When the bank 154 is formed of a material containing black pigment or black dye, it is possible to block external light or light reflected from the outside, thereby further increasing the luminance of the display apparatus.

A spacer 155 can be further disposed on the bank 154. The spacer 155 can be formed of the same material as the bank 154, but the embodiments of the present disclosure are not limited thereto. For example, the spacer 155 can be a transparent bank, but is not limited thereto, and the spacer 155 can be formed of the same material as the bank 154. For example, the spacer 155 can be disposed on at least one of the boundaries of the first to third sub-pixels PX1, PX2, and PX3, but the embodiments of the present disclosure are not limited thereto. In some embodiments, the bank 154 and the spacer 155 can be formed of the same material and formed simultaneously through a halftone mask, but the embodiments of the present disclosure are not limited thereto.

The organic layer 152 can be disposed on the anode electrode 151, the bank 154, and the spacer 155. The cathode electrode 153 can be disposed on the organic layer 152.

The encapsulation part 170 can be disposed on the cathode electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

The touch part 180 can be disposed on the encapsulation part 170. The touch part 180 can include the touch buffer layer 181, a first touch conductive layer 182, and a touch organic layer 190.

The touch buffer layer 181 can be disposed on the third encapsulation layer 173. The touch buffer layer 181 can be formed of the same material as the buffer layer 102, but the embodiments of the present disclosure are not limited thereto.

The first touch conductive layer 182 can be disposed on the touch buffer layer 181. The first touch conductive layer 182 can include a sensor electrode SC. The sensor electrode SC can be disposed in the non-light-emitting areas NEA1, NEA2, and NEA3 and may not be disposed in the light-emitting areas EA1, EA2, and EA3. The sensor electrode SC can be disposed on boundaries between adjacent sub-pixels PX1, PX2, and PX3.

The first touch conductive layer 182 can include a metallic material. For example, the first touch conductive layer 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

The touch organic layer 190 can be disposed on the first touch conductive layer 182. The touch organic layer 190 can include an organic insulation material, but the embodiments of the present disclosure are not limited thereto.

However, the configuration of the touch layer 180 is not limited thereto, and the touch layer 180 can include two or more touch conductive layers. For example, the touch layer 180 can include a buffer layer, a bridge electrode disposed on the buffer layer, a touch insulating layer disposed on the bridge electrode, a touch conductive layer disposed on the touch insulating layer, and a touch organic layer disposed on the touch conductive layer.

A polarizing film or a color filter can be disposed on the touch part 180, but the embodiments of the present disclosure are not limited thereto.

Hereinafter, the non-display area NDA of the display panel according to aspects of the present disclosure will be described.

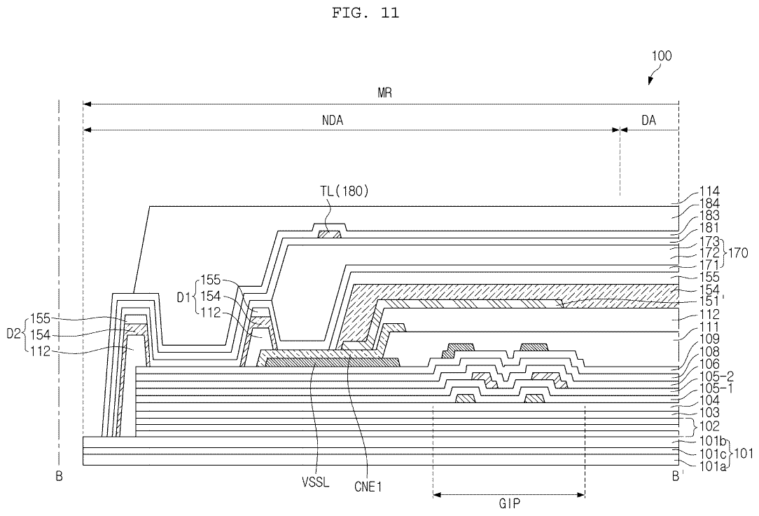

FIG. 11 is a cross-sectional view along line B-B′ in FIG. 1.

Referring to FIG. 11, at least one of the panel inorganic layers 102, 103, 104, 105-1, 105-2, 106, 108, and 109 may not extend to an end of the substrate 101. For example, the at least one of the panel inorganic layers 102, 103, 104, 105-1, 105-2, 106, 108, and 109 can expose the end of the substrate 101, but the embodiments of the present disclosure are not limited thereto.

The display panel 100 according to one embodiment can further include the crack sensing pattern, the low-potential voltage line VSSL, and the gate driving unit GIP. As described above in FIG. 1, the low-potential voltage line VSSL can be located between the crack sensing pattern and the display area DA, and the gate driving unit GIP can be located between the low-potential voltage line VSSL and the display area DA.

For example, as illustrated in FIG. 6, the gate driving unit GIP can be formed of a conductive layer located on the same layer as the first gate electrode 122 (see FIG. 8), a conductive layer located on the same layer as the second light-blocking layer 136 (see FIG. 8), or a conductive layer located on the same layer as the first source electrode 121, but the embodiments of the present disclosure are not limited thereto.

The low-potential voltage line VSSL can be disposed between dams D1 and D2 and the gate driving unit GIP. The low-potential voltage line VSSL can be formed of a conductive layer located on the same layer as the first source electrode 121, but the embodiments of the present disclosure are not limited thereto.

The first protective layer 111 can cover the gate driving unit GIP, partially cover one end portion of the low-potential voltage line VSSL, and expose the other end portion of the low-potential voltage line VSSL. In the present disclosure, the one end portion can refer to an area of a certain component, which is located in a direction from the non-display area NDA toward the display area DA, and the other end portion can refer to an area of the certain component, which is located in a direction from the display area DA toward the non-display area NDA.

A first connection electrode CNE1 located on the same layer as the connection electrode 145 can be disposed on the first protective layer 111. The first connection electrode CNE1 can be directly connected to an area of the low-potential voltage line VSSL, in which the first protective layer 111 is exposed. The first connection electrode CNE1 can cover the other end portion of the low-potential voltage line VSSL, but the embodiments of the present disclosure are not limited thereto.

The second protective layer 112 can be disposed on the first connection electrode CNE1. The second protective layer 112 can come into direct contact with and cover one end portion of the first connection electrode CNE1 and expose the other end portion of the first connecting electrode CNE1.

The second protective layer 112 can form a first layer of a first dam D1 and a first layer of a second dam D2. The first dam D1 can overlap, for example, the low-potential voltage line VSSL and cover the other end portion of the low-potential voltage line VSSL. The first dam D1 can come into direct contact with the first connection electrode CNE1 and cover the other end portion of the first connection electrode CNE1. The second protective layer 112 forming the first layer of the second dam D2 can be in direct contact with the exposed side surface of at least one of the panel inorganic layers 102, 103, 104, 105-1, 105-2, 106, 107, and 109 and can be in direct contact with the upper surface of the substrate 101, but the embodiments of the present disclosure are not limited thereto. The second protective layer 112 can overlap the gate driving unit GIP. In the present disclosure, the dam is, for example, provided as two dams, but the dam can be provided as three or more dams or one dam.

A low-potential connection electrode 151′ located on the same layer as the anode electrode 151 (see FIG. 8) can be disposed on the first connection electrode CNE1 exposed by the second protective layer 112 and the second protective layer 112. The low-potential connection electrode 151′ can be electrically connected to the first connection electrode CNE1 exposed by the second protective layer 112. The low-potential connection electrode 151′ can be electrically connected to the cathode electrode 153 (see FIG. 8) described above in FIG. 8.

The bank 154 can be disposed on the low-potential connection electrode 151′ and the second protective layer 112. The bank 154 can overlap the gate driving unit GIP, overlap the low-potential connection electrode 151′, and cover the other end portion of the low-potential connection electrode 151′. The bank 154 can completely cover the low-potential connection electrode 151′, but the embodiments of the present disclosure are not limited thereto. The bank 154 can expose a central portion and the other end portion of the first connection electrode CNE1, but the embodiments of the present disclosure are not limited thereto. The bank 154 can form a second layer of the first dam D1 and a second layer of the second dam D2. In each dam D1 or D2, the bank 154 can overlap the second protective layer 112 forming the first layer and completely cover the second protective layer 112, but the embodiments of the present disclosure are not limited thereto. In the second dam D2, the bank 154 can come into contact with the side surfaces of the second protective layer 112 and the upper surface of the substrate 101, but the embodiments of the present disclosure are not limited thereto. When the bank is formed of two or more layers, the second bank can form the third layers of the dams D1 and D2.

The spacer 155 can form the third layer of the first dam D1 and the third layer of the second dam D2. In each dam D1 or D2, the spacer 155 can overlap the bank 154 forming the second layer. In the second dam D2, the spacer 155 can overlap the bank 154 forming the second layer.

The encapsulation part 170 can be disposed on the spacer 155. The first encapsulation layer 171 can extend to the gate driving unit GIP, the low-potential voltage line VSSL, the first dam D1, and the second dam D2 and cover an outer surface of the second dam D2. The second encapsulation layer 172 can end at the first dam D1. The second encapsulation layer 172 can overlap the gate driving unit GIP and the low-potential voltage line VSSL. The third encapsulation layer 173 can extend to the gate driving unit GIP, the low-potential voltage line VSSL, the first dam D1, and the second dam D2 and can be in direct contact with the first encapsulation layer 171 on the first dam D1, the crack sensing pattern, and the second dam D2.

The touch buffer layer 181 can extend to the gate driving unit GIP, the low-potential voltage line VSSL, the first dam D1, and the second dam D2 and cover an outer surface of the second dam D2.

The touch part 180 can further include a touch line TL. The touch line TL can be disposed on the first touch conductive layer 182. The touch line TL can be formed of the first touch conductive layer 182. The first touch conductive layer 182 can further include the touch line TL.

The touch line TL can be electrically connected to the sensor electrode SC (see FIG. 8). The touch line TL can electrically connect at least one of the flexible film COF (see FIG. 1), the drive IC DIC (see FIG. 1), and the printed circuit board FPCB (see FIG. 1) to the sensor electrode SC (see FIG. 8).

The touch line TL can overlap the low-potential voltage line VSSL in the thickness direction, but the embodiments of the present disclosure are not limited thereto. The touch organic layer 190 can extend to the gate driving unit GIP, the low-potential voltage line VSSL, the first dam D1, and the crack sensing pattern and can be ended on the second dam D2, but the embodiments of the present disclosure are not limited thereto.

Hereinafter, other embodiments of the present disclosure will be described. For contents that are substantially the same as those described with reference to FIGS. 1 to 11 among components included in other embodiments, the same reference numerals are given, and overlapping contents can be omitted or briefly described.

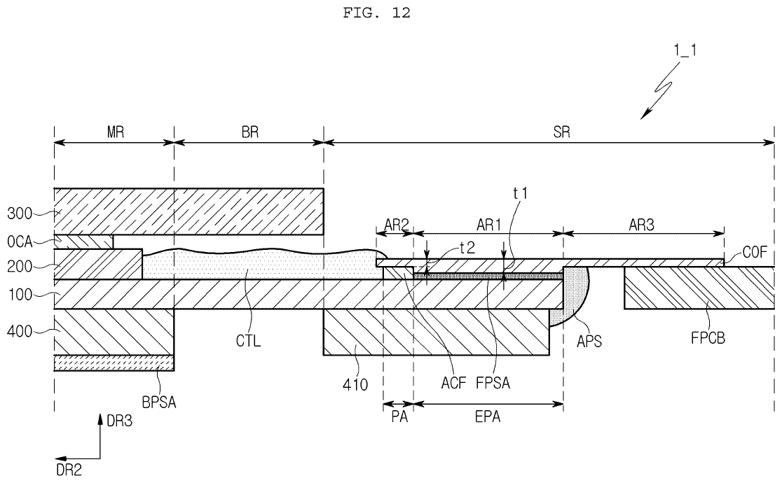

FIG. 12 is a cross-sectional view of a display apparatus according to yet another embodiment of the present disclosure.

For convenience of description, FIG. 12 illustrates a cross section of the display panel 100 that is not bent.

Referring to FIG. 12, a display apparatus 1_1 according to the present embodiment can further include a film adhesive member FPSA disposed between the display panel 100 and the flexible film COF.

The film adhesive member FPSA can be disposed between the dummy area EPA of the display panel 100 and the first film portion AR1 of the flexible film COF. The film adhesive member FPSA can include a PSA. When the film adhesive member FPSA includes a PSA, the film adhesive member FPSA can be a double-sided adhesive.

At least one of upper and lower surfaces of the film adhesive member FPSA can have a pattern before attachment is performed. For example, the pattern can be an embossing pattern or a protruding dot pattern, but is not limited thereto. Accordingly, it is possible to increase the adhesion efficiency of the film adhesive member FPSA.

The first film portion AR1 can have a greater thickness than the second film portion AR2 and the third film portion AR3 and protrude toward the display panel 100.

Accordingly, even when the dummy area EPA is disposed outside (at the other side in the second direction DR2) of the pad area PA and includes dummy circuits and/or dummy electrodes, the first film portion AR1 can smoothly fill the spacing space between the flexible film COF and the dummy area EPA) without being affected by the length of the dummy area EPA in the second direction DR2.

Since the flexible film COF has a relatively great thickness in the area in which it overlaps the dummy area EPA, the flexible film COF and the display panel 100 can be fixed more efficiently and smoothly, thereby improving the structural stability of the display apparatus 1_1. Furthermore, it is possible to suppress or prevent damage to the flexible film COF and the display panel 100 due to a collision between the flexible film COF and the display panel 100, increase the life of the display apparatus, and reduce power consumption.

Furthermore, since the film adhesive member FPSA is further disposed between the first film portion AR1 and the dummy area EPA, the flexible film COF and the display panel 100 can be more firmly fixed, thereby further improving the structural stability of the display apparatus 1_1.

A display apparatus according to various embodiments of the present disclosure can be described as follows.

According to embodiments of the present disclosure, there is provided a display apparatus including a display panel including a main region, a sub-region including a pad area disposed inward more than an end of a substrate, and a bending region between the main region and the sub-region, and a flexible film attached to the sub-region on the substrate of the display panel, in which the flexible film includes a first film portion overlapping an area between the pad area and the end of the substrate and having a first thickness, and a second film portion overlapping the pad area and having a second thickness smaller than the first thickness.

According to various embodiments of the present disclosure, the display apparatus can further include an anisotropic conductive film between the second film portion and the substrate.

According to various embodiments of the present disclosure, the display apparatus can further include a pad electrode between the substrate and the anisotropic conductive film, and a lead electrode between the second film portion and the anisotropic conductive film, in which the pad electrode and the lead electrode can be electrically connected through the anisotropic conductive film.

According to various embodiments of the present disclosure, a lower surface of the first film portion can be in contact with the display panel.

According to various embodiments of the present disclosure, the display apparatus can further include a film adhesive member between the first film portion and the display panel, in which the first film portion and the display panel can be coupled through the film adhesive member.

According to various embodiments of the present disclosure, the display apparatus can further include an encapsulation member disposed on a side surface of the sub-region of the display panel.

According to various embodiments of the present disclosure, the encapsulation member can be in direct contact with the first film portion and may not be in contact with the second film portion.

According to various embodiments of the present disclosure, the display apparatus can further include a polarizing layer on the display panel, a cover layer on the polarizing layer, and a bonding member between the polarizing layer and the cover layer, in which an end of the bonding member can be disposed inward more than an end of the polarizing layer.

According to various embodiments of the present disclosure, the display apparatus can further include a protective coating layer disposed on a bending region of the display panel, in which the protective coating layer can be in contact with the polarizing layer.

According to various embodiments of the present disclosure, the sub-region can further include a dummy area between the pad area and an end of the display panel, and a dummy line can be disposed in the dummy area.

According to various embodiments of the present disclosure, the display apparatus can further include a printed circuit board connected to the flexible film, in which the display panel can be bent thereunder in the bending region, and the display apparatus can further include a lower adhesive between the printed circuit board and a lower surface of the display panel.

According to various embodiments of the present disclosure, the display apparatus can further include a back plate between the display panel and the lower adhesive.

According to various embodiments of the present disclosure, the display apparatus can further include a protective tape under the printed circuit board.

According to embodiments of the present disclosure, there is provided a display apparatus including a display panel including a main region, a sub-region including a pad area disposed inward more than an end of a substrate, and a bending region between the main region and the sub-region, and a flexible film attached to the sub-region on the substrate of the display panel and having different thicknesses for each region, in which the display panel includes a substrate, a first transistor on the substrate, a second transistor on the first transistor, a first protective layer on the second transistor, a connection electrode connected to the second transistor on the first protective layer, a second protective layer on the connection electrode, a light-emitting part disposed on the protective layer and connected to the connection electrode, an encapsulation layer on the light-emitting part, and a touch part disposed on the encapsulation layer, and the touch part includes a touch buffer layer, a touch conductive layer on the touch buffer layer, and a touch organic layer on the touch conductive layer.

According to various embodiments of the present disclosure, the flexible film can include a first film portion overlapping an area between the pad area and the end of the substrate and having a first thickness, and a second film portion overlapping the pad area and having a second thickness smaller than the first thickness.

According to various embodiments of the present disclosure, the display apparatus can further include an anisotropic conductive film between the second film portion and the substrate.

According to various embodiments of the present disclosure, the display apparatus can further include a pad electrode between the substrate and the anisotropic conductive film, and a lead electrode between the second film portion and the anisotropic conductive film, in which the pad electrode and the lead electrode can be electrically connected through the anisotropic conductive film.

According to various embodiments of the present disclosure, a lower surface of the first film portion can be in contact with the display panel.

According to various embodiments of the present disclosure, the display apparatus can further include a film adhesive member between the first film portion and the display panel, in which the first film portion and the display panel can be coupled through the film adhesive member.

According to various embodiments of the present disclosure, the display apparatus can further include an encapsulation member disposed on a side surface of the sub-region, in which the encapsulation member can be in direct contact with the first film portion and may not be in contact with the second film portion.

Although the embodiments of the present disclosure have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
100: display apparatus
200: polarizing layer
300: cover layer
400: back plate
COF: flexible film
AR1 to AR3: first to third film portions
PA: pad area
EPA: dummy area
FPCB: printed circuit board
ACF: conductive adhesive
CTL: protective coating layer

What is claimed is:

1. A display apparatus comprising:
a display panel including a main region, sub-region including a pad area disposed inwardly more than an end of a substrate, and a bending region between the main region and the sub-region; and
a flexible film attached to the sub-region on the substrate of the display panel,
wherein the flexible film includes:
a first film portion overlapping an area between the pad area and the end of the substrate and having a first thickness; and
a second film portion overlapping the pad area and having a second thickness smaller than the first thickness.

2. The display apparatus of claim 1, further comprising an anisotropic conductive film between the second film portion and the substrate.

3. The display apparatus of claim 2, further comprising:
a pad electrode between the substrate and the anisotropic conductive film; and
a lead electrode between the second film portion and the anisotropic conductive film,
wherein the pad electrode and the lead electrode are electrically connected through the anisotropic conductive film.

4. The display apparatus of claim 1, wherein a lower surface of the first film portion of the flexible film is in contact with the display panel.

5. The display apparatus of claim 1, further comprising a film adhesive member between the first film portion of the flexible film and the display panel,
wherein the first film portion of the flexible film and the display panel are coupled through the film adhesive member.

6. The display apparatus of claim 1, further comprising an encapsulation member disposed on a side surface of the sub-region of the display panel.

7. The display apparatus of claim 6, wherein the encapsulation member is in direct contact with the first film portion of the flexible film and is not in contact with the second film portion of the flexible film.

8. The display apparatus of claim 1, further comprising:
a polarizing layer on the display panel;
a cover layer on the polarizing layer, and
a bonding member between the polarizing layer and the cover layer,
wherein an end of the bonding member is disposed inwardly more than an end of the polarizing layer.

9. The display apparatus of claim 8, further comprising a protective coating layer disposed on the bending region of the display panel,
wherein the protective coating layer is in contact with the polarizing layer.

10. The display apparatus of claim 1, wherein the sub-region further includes a dummy area between the pad area and an end of the display panel, and
wherein a dummy line is disposed in the dummy area.

11. The display apparatus of claim 1, further comprising a printed circuit board connected to the flexible film,
wherein the display panel is bent thereunder in the bending region, and
wherein the display apparatus further includes a lower adhesive between the printed circuit board and a lower surface of the display panel.

12. The display apparatus of claim 11, further comprising a back plate between the display panel and the lower adhesive.

13. The display apparatus of claim 11, further comprising a protective tape under the printed circuit board.

14. A display apparatus comprising:
a display panel including a main region, sub-region including a pad area disposed inwardly more than an end of a substrate, and a bending region between the main region and the sub-region; and
a flexible film attached to the sub-region on the substrate of the display panel and having different thicknesses,
wherein the display panel includes:
the substrate;
a first transistor on the substrate;
a second transistor on the first transistor;
a first protective layer on the second transistor,
a connection electrode connected to the second transistor on the first protective layer;
a second protective layer on the connection electrode;
a light-emitting part disposed on the second protective layer and connected to the connection electrode;
an encapsulation layer on the light-emitting part; and
a touch part disposed on the encapsulation layer,
wherein the touch part includes a touch buffer layer, a touch conductive layer on the touch buffer layer, and a touch organic layer on the touch conductive layer.

15. The display apparatus of claim 14, wherein the flexible film includes:
a first film portion overlapping an area between the pad area and the end of the substrate, and having a first thickness; and
a second film portion overlapping the pad area, and having a second thickness smaller than the first thickness.

16. The display apparatus of claim 15, further comprising an anisotropic conductive film between the second film portion of the flexible film and the substrate.

17. The display apparatus of claim 16, further comprising:
a pad electrode between the substrate and the anisotropic conductive film; and
a lead electrode between the second film portion and the anisotropic conductive film,
wherein the pad electrode and the lead electrode are electrically connected through the anisotropic conductive film.

18. The display apparatus of claim 15, wherein a lower surface of the first film portion of the flexible film is in contact with the display panel.

19. The display apparatus of claim 15, further comprising a film adhesive member between the first film portion of the flexible film and the display panel,
wherein the first film portion of the flexible film and the display panel are coupled through the film adhesive member.

20. The display apparatus of claim 15, further comprising an encapsulation member disposed on a side surface of the sub-region of the display panel,
wherein the encapsulation member is in direct contact with the first film portion of the flexible film and is not in contact with the second film portion of the flexible film.
